(19) United States
(12) Patent Application Publication
(10) Pub. No.: US 2021/0234342 A1
(43) Pub. Date: Jul. 29, 2021

(54) Matrix-Addressable VCSEL for Solid-State LiDAR

(71) Applicant: OPSYS Tech Ltd., Holon (IL)

(72) Inventor: Mark J. Donovan, Mountain View, CA (US)

(73) Assignee: OPSYS Tech Ltd., Holon (IL)

(21) Appl. No.: 17/155,626

(22) Filed: Jan. 22, 2021

Related U.S. Application Data
(60) Provisional application No. 62/965,161, filed on Jan. 23, 2020.

(51) Int. Cl. H01S 5/42; H01S 5/042; G01S 17/88

(52) U.S. Cl. CPC H01S 5/423; G01S 17/88; H01S 5/04256

(57) ABSTRACT

A matrix-addressable vertical cavity surface emitting laser array for light detection and ranging systems includes a plurality of rows of vertical cavity surface emitting lasers formed on a die with one row of vertical cavity surface emitting lasers comprising a plurality of vertical cavity surface emitting lasers each configured with a common cathode electrical connection on one side of the die and another row of vertical cavity surface emitting lasers comprising a plurality of vertical cavity surface emitting lasers each configured with a common cathode electrical connection on the other side of the die. Each of the rows of vertical cavity surface emitting lasers is configured with anode connections that allow activating only a portion of the row at a particular time so that Class 1 eye safety can be maintained.

### CROSS REFERENCE TO RELATED APPLICATION

The present application is a non-provisional application of U.S. Provisional Patent Application Ser. No. 62/965,161 entitled “Matrix-Addressable VCSEL for Solid-State LiDAR” filed on Jan. 23, 2020. The entire content of U.S. Provisional Patent Application Ser. No. 62/965,161 is herein incorporated by reference.

### INTRODUCTION

Autonomous, self-driving, and semi-autonomous automobiles use a combination of different sensors and technologies such as radar, image-recognition cameras, and sonar for detection and location of surrounding objects. These sensors enable a host of improvements in driver safety including collision warning, automatic-emergency braking, lane-departure warning, lane-keeping assistance, adaptive cruise control, and piloted driving. Among these sensor technologies, light detection and ranging (LiDAR) systems take a critical role, enabling real-time, high-resolution 3D mapping of the surrounding environment.

Most current LiDAR systems used for autonomous vehicles today utilize a small number of lasers, combined with some method of mechanically scanning the environment. Some state-of-the-art LiDAR systems use two-dimensional Vertical Cavity Surface Emitting Lasers (VCSEL) arrays as the illumination source. It is highly desirable for future autonomous cars to utilize solid-state semiconductor-based LiDAR systems with high reliability and wide environmental operating ranges. These systems are advantageous because they have no moving parts and can be highly reliable. However, currently state-of-the-art LiDAR systems have many practical limitations.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings, described below, are for illustration purposes only. The drawings are not necessarily to scale; emphasis instead generally being placed upon illustrating principles of the teaching. The drawings are not intended to limit the scope of the Applicant's teaching in any way.

FIG. 1 illustrates a top-view of a known Vertical Cavity Surface Emitting Laser array.

FIG. 2A illustrates a top-view of an embodiment of a Vertical Cavity Surface

Emitting Laser array for a LiDAR system according to the present teaching.

FIG. 2B illustrates a top perspective view of a portion of the Vertical Cavity Surface Emitting Lasers array described in connection with FIG. 2A showing more details of the laser structure and the electrodes.

FIG. 2C illustrates an embodiment of the physical layout of a transmitter for a LiDAR system including the Vertical Cavity Surface Emitting Lasers array described in connection with FIG. 2A that shows the laser drivers.

FIG. 3 illustrates a top view of another embodiment of a Vertical Cavity Surface Emitting Laser array for a LiDAR system according to the present teaching.

FIG. 4 illustrates a top-view of a layout of a Vertical Cavity Surface Emitting Laser array for a LiDAR system with single-ended cathodes according to the present teaching.

FIG. 5 illustrates a top-view of a layout of a Vertical Cavity Surface Emitting Laser array for a LiDAR system with single-ended anodes according to the present teaching.

### DESCRIPTION OF VARIOUS EMBODIMENTS

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the method of the present teaching can be performed in any order and/or simultaneously as long as the teaching remains operable. Furthermore, it should be understood that the apparatus and method of the present teaching can include any number or all of the described embodiments as long as the teaching remains operable.

The present teaching relates to Light Detection and Ranging (LiDAR), which is a remote sensing method that uses laser light to measure distances (ranges) to objects. Autonomous vehicles make use of LiDAR systems to generate a highly accurate 3D map of the surrounding environment with fine resolution. The systems and methods described herein are directed towards providing a solid-state, pulsed time-of-flight (TOF) LiDAR system with high levels of reliability, while also maintaining long measurement range as well as low cost.

In addition, the systems and methods described herein that provide solid-state pulsed TOF LiDAR are also configured to maintain Class 1 eye safety. A Class 1 eye safety rating means the system is safe under all conditions of normal use. To maintain Class 1 eye safety, the laser optical energy or laser optical power cannot exceed a maximum permissible exposure (MPE) level as defined by U.S. and international safety standards. However, the measurement range of a LiDAR system is strongly dependent on the maximum transmitted optical pulse energy or power level. Therefore, it is desirable for automotive LiDAR systems to intentionally operate as close to the Class 1 MPE limit as feasible. Hence, the configuration and layout of the two-dimensional VCSEL array is critical to achieving optimal performance.

Individual lasers in two-dimensional VCSEL array are activated in predetermined sequences to illuminate different points or regions of interest to be measured by the LiDAR system. The resolution and/or field-of-view (FOV) of the system is determined by which lasers are activated in the two-dimensional VCSEL array. It follows then for systems with fine resolution and/or large field-of-view, the number of lasers is very large, and can be in the hundreds or even many thousands of individual lasers. Individually driving very large numbers of lasers in a two-dimensional VCSEL array with separate laser drivers makes the resulting LiDAR transmitter system relatively large, complex and costly.

One feature of the present teaching is the use of matrix-addressing in LiDAR transmitters using two-dimensional VCSEL arrays to reduce the physical size, complexity and cost of the LiDAR transmitter. Using matrix-addressing of the two-dimensional VCSEL array according to the present teaching is desirable because it provides the ability to activate individual lasers without needing an individual laser driver per each laser. With matrix-addressing, the number of laser drivers scales on the order of N+M instead of scaling on order of N*M, where N and M are integer numbers of shared anode and cathode electrical contacts, respectively.

In various embodiments of the LiDAR systems according to the present teaching, the geometry of the two-dimensional VCSEL array and the particular layout of the individual lasers can be improved or optimized based on numerous design constraints including the desired optical output power for each laser, the laser optical efficiency, the maximum laser bias current, the desired size of the individual and total optical emission areas, eye safety power limitations, inductance/impedance of the electrical circuit, RF pulse characteristics, as well as other physical, optical and electrical design constraints. Thus, the present teaching relates, at least in part, to various configurations for matrix-addressable VCSEL arrays specifically configured for solid-state LiDAR system that addresses at least some of these constraints. For example, one aspect of the present teaching is that the matrix-addressable vertical cavity surface emitting laser can be configured so that at least one of the rows of vertical cavity surface emitting lasers has anode connections that allow activating a portion of the vertical cavity surface emitting lasers in the at least one row of vertical cavity surface emitting lasers with a particular bias current so that Class 1 eye safety is maintained if vertical cavity surface emitting lasers in that portion of the row of vertical cavity surface emitting lasers are activated and Class 1 eye safety is exceeded if the entire at least one row of vertical cavity surface emitting lasers is activated. Also, the plurality of vertical cavity surface emitting lasers can each be configured with the common cathode electrical connection on one side of the die with anode connections that allow activating a portion of the vertical cavity surface emitting lasers in a row of vertical cavity surface emitting lasers with a particular bias current so that Class 1 eye safety is maintained if vertical cavity surface emitting lasers in that portion of the row of vertical cavity surface emitting lasers are activated and Class 1 eye safety is exceeded if that entire row of vertical cavity surface emitting lasers is activated.

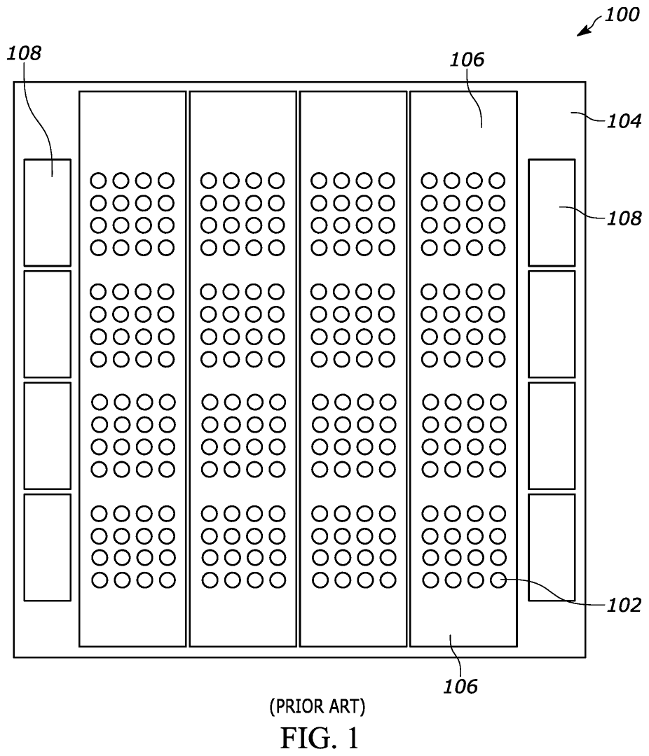

FIG. 1 illustrates a top-view of a known matrix-addressable Vertical Cavity Surface Emitting Laser (VCSEL) array 100. More specifically, FIG. 1 illustrates a top-view of a top-illuminated, two-dimensional VCSEL array having 16 individual lasers, where each of the 16 laser VCSEL has 16 apertures 102. An individual laser, also referred to herein as an individual emitter, laser element, or array element, is an element that is individually addressable such that an applied electrical signal causes the emitter to produce a beam of light. In various embodiments, various numbers of apertures are included in an individual laser, emitter, or element. In the configuration shown in FIG. 1, electrical contact to the VCSEL array is made at the edges of the die 104, where there is physical space to make electrical contact with connections that are physically large enough to carry the required electrical current. Often the electrical contacts are made using wire bonding techniques.

Wire bonds or other electrical contacts are made between the anodes and cathodes of the lasers and the driver circuit. The physical size of the electrical contact area can be a limiting factor in some designs. A typical contact can be on the order of 250 microns in the widest dimension. Because of the fast rise/fall times involved in pulse operation of state-of-the art LiDAR systems, it is often desirable to have a large electrical contact pad with multiple wire bonds and/or gold ribbon in order to minimize the undesirable inductance of the wire bond and the associated impedance. Larger cross-section wires and/or multiple bonds also result in higher electrical current carrying capacity, which is highly desirable.

The electrical contacts 106 to the VCSEL array 100 at the top and bottom of the matrix-addressable VCSEL array 100 are electrical contacts to the laser anodes, which are p-type semiconductor electrical contact. The electrical contact 108 to the left and right of the matrix-addressable VCSEL array 100 are electrical contacts to the laser cathodes of the matrix, which are the n-type electrical contacts. By appropriately biasing the electrical contacts 106, 108 of each row/column, the individual lasers within the matrix are activated. A controller or processor typically instructs an electrical bias circuit to bias particular row/column locations within the matrix in a predetermined sequence according to the desired operation while simultaneously maintaining eye-safety constraints. In this known VCSEL configuration shown in FIG. 1, the VCSEL array geometry is symmetric, with each shared anode having contacts at both the top and bottom of the VCSEL array, and each shared cathode having contacts at both the left and right side. One aspect of the present teaching is the realization that this contact geometry limits the size of an individually-addressable laser element.

In this example array 100, the individually-addressable laser element has sixteen emitters 102 that share a common anode 106 and cathode 108 electrode. The array of the groups of sixteen emitters 102 has a pitch in the vertical dimension that is equal to the pitch of the electrodes 108. The array of groups of sixteen emitters 102 has a pitch in the horizontal dimension that is equal to the pitch of the anode electrodes 106. Thus, the size of an addressable laser element that includes the sixteen emitters is the pitch of the anode emitters times the pitch of the cathode emitters. Because the contact electrode size needs to be large as described herein, new connection approaches are needed so the physical size of the group of laser emitters that is commonly addressed by a contact electrode can be physically smaller than the contact electrode size and/or the spacing between electrodes (pitch).

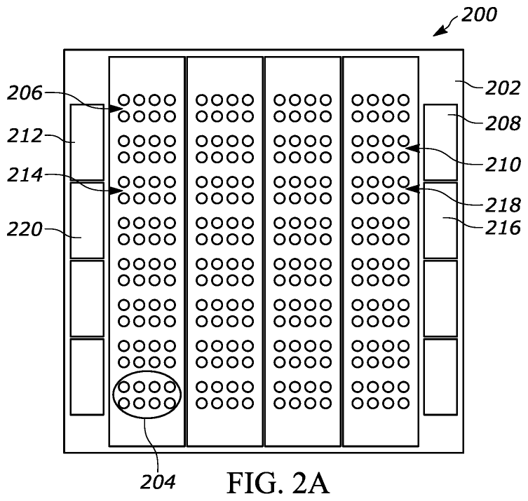

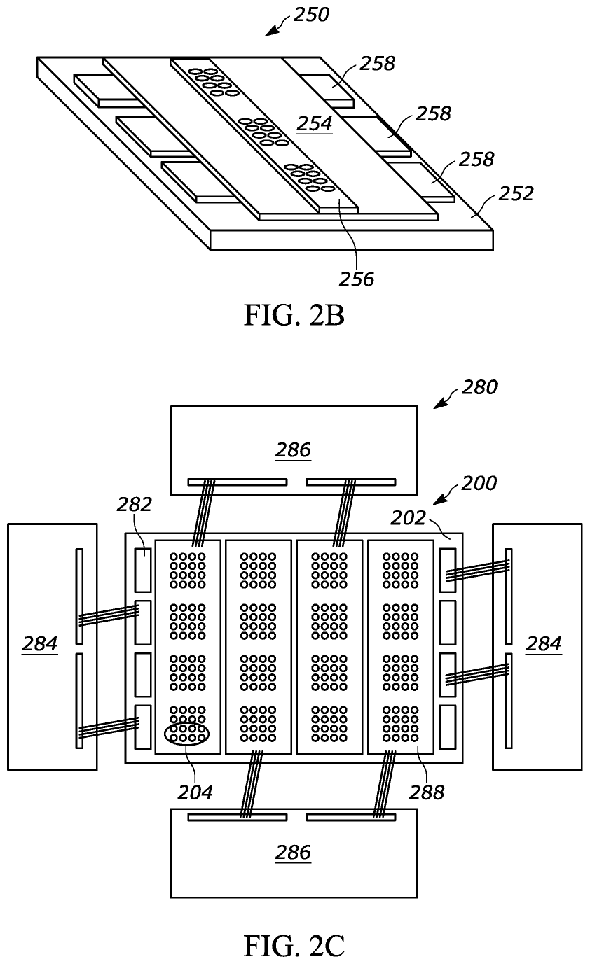

FIG. 2A illustrates a top-view of an embodiment of a Vertical Cavity Surface Emitting Lasers array 200 for a LiDAR system according to the present teaching. Compared to the known VCSEL configuration described in connection with FIG. 1, the overall dimension and number of contact pads on the edges of the die 202 are the same as in the examples given in FIG. 1 an FIG. 3. However, the configuration of the VCSEL laser shown in FIG. 2A is beneficially able to include significantly more individually-addressable laser elements than the known configuration described in connection with FIG. 1. One feature of this and various other embodiments of the present teaching is that the electrical contact configuration has a significantly larger number of individually addressable lasers, or laser emitter groups, for a particular overall dimension and a particular number of contact pads on the edges of a particular die size as compared to prior art electrical contact configurations.

For example, in the VCSEL configuration shown in FIG. 2A, there are 32 VCSEL lasers 204 in the array 200, each with 8 apertures. In the configuration shown in FIG. 1 there are 16 VCSEL lasers in the array 100, each with 16 apertures. Thus, the pitch in the vertical dimension of the lasers 204 in array 200 of FIG. 2A is half of the pitch in the vertical dimension of the lasers in array 100 of FIG. 1. Thus, the array anode and cathode connection configuration of the present teaching provides a larger number of individually addressable emitters per unit area than the known array anode and cathode configuration shown in FIG. 1. In addition, the resulting larger contact pad sizes can be advantageous for manufacturing and/or the application of wire bonds. The ability to have the individual laser emitter group size not tied directly to the size of the contact, and in particular to be smaller than the contact size, leads to a significant advance in the state-of-the art. In particular, the ability to have the individual laser emitter group size be independent of the size of the contact leads to an improvement in, for example, the cost, size and/or complexity of the transmitter while also providing improved resolution and/or control over size, position and/or optical power of emitted optical beams.

In various embodiments of the present teaching, more individually addressed emitters (lasers 204) are achieved per unit area with more control because each row of emitters has a cathode contact on only one side of the die 202. A row is referred to herein generally as a group of lasers that are individually addressable. For example, in the configuration shown in FIG. 2A, the top row 206 of emitters are electrically connected to the topmost, right cathode contact 208 and the second row 210 of emitters corresponds to the topmost, left cathode contact 212. In some configurations, an alternating pattern of electrical connections continues where, for example, the third row 214 of emitters are electrically connected to the second right cathode contact 216 and the fourth row 218 of emitters are electrically connected to the second left cathode contact 220. Thus, the pitch of the electrical connections to the cathodes in the vertical dimension of array 200 is twice the pitch of the rows of lasers 206, 210, 214, 218. The electrical pitch is given by the spacing between contact 212 and contact 220, or, alternatively the pitch between contact 208 and contact 216. Thus, the optical pitch is half the electrical pitch in the vertical dimension.

The increased number of lasers in a given array size that are individually controlled is achievable because each row of emitters has a cathode contact on only one side of the die 202. That is, by having at least some adjacent rows, e.g. a top row and a bottom row, of emitters connected to a cathode electrode such that the top row is connected on one side of the array and the bottom row is connected on the other side of the array, the two rows become individually addressable. Since a row refers to a group of lasers that are individually addressable, these rows may have a vertical extent of one, two or more lasers, depending on the configuration. Importantly, the pitch of an individually addressable row is not necessarily the same as the pitch of the cathodes, and in particular, the individually addressable rows are more closely spaced than the cathode electrodes.

FIG. 2B illustrates a top perspective view of a portion of the Vertical Cavity Surface Emitting Lasers (VCSEL) array 250 described in connection with FIG. 2A showing more details of the laser structure and the electrodes. The top perspective view of the portion of the VCSEL lasers array 250 includes three VCSEL lasers with 8 apertures each. This perspective view shows the substrate 252, which for many applications is a gallium arsenide substrate, and the vertical laser cavity structure 254. The common anode contact 256 for the three VCSEL lasers with 8 apertures each is also shown. In addition, the three separate cathode contacts 258, one for each of the three VCSEL lasers, is shown. The VCSEL lasers shown in FIG. 2B are top emitting VCSEL lasers. It should be understood that that the VCSEL lasers can be top emitting, bottom emitting, and can also be configured as vertical external-cavity surface emitting lasers.

FIG. 2C illustrates an embodiment of the physical layout of a transmitter 280 for a LiDAR system including the Vertical Cavity Surface Emitting Lasers array 200 described in connection with FIG. 2A that shows the laser drivers. The VCSEL array 200 of FIG. 2A is shown with the die 202 and individually address emitters 204. There are four cathode contacts 282 on each side of the transmitter 280. Low side drivers 284 are electrically connected to alternating cathode connections 282 on each side of the transmitter 280. High side drivers 286 are electrically connected to alternating anode connections 288.

The electrical contact arrangement described in connection with FIGS. 2A-C allows a smaller pitch of individually addressable lasers in at least one dimension (the vertical dimension as illustrated in FIGS. 2A-C) as compared to the known configuration described in connection with FIG. 1. In this example, there are eight individually addressable emitters in the array 200 that share a common anode electrode and cathode electrode, as compared to sixteen in the FIG. 1 array 100. This resulting decrease in the pitch of individually addressable lasers, also referred to as groups of laser emitters, can be used to achieve various performance objectives such as achieving higher resolution and/or greater field-of-view. For example, the resolution in the vertical direction of a system that uses the array 200 of FIG. 2A can be twice the resolution of a system that uses the array 100 of FIG. 1. In addition, potentially smaller physical laser size achievable with this configuration can be used to address the many constraints of solid state LiDAR system, such as eye safety or laser efficiency constraints.

FIG. 3 illustrates a top view of another embodiment of a Vertical Cavity Surface Emitting Laser array 300 for a LiDAR system according to the present teaching. The electrical contacts for the rows of the VCSEL array 300 configuration shown in FIG. 3 is similar to the VCSEL array 200 configuration described in connection with FIG. 2A in that each row of emitters has a cathode contact on only one side of the die 302. The array 300 has individually addressable laser elements 304 with four apertures. The first row 306 of laser elements 304 is connected to a contact 308 on one side of die 302 and the second row 310 of laser elements 304 is connected to a contact 312 on the other side of die 302. A third row 313 of lasers is connected to contact 314 on the same side as the contact 308. Additional rows are connected in this alternating manner. The first column of laser elements 304 is connected to top contact 316, which is an anode contact. The second column of laser elements 304 is connected to bottom contact 318, which is also an anode contact. The third column of laser elements 304 is connected to top contact 320, which is also an anode contact.

Thus, the electrode configuration described in connection with FIG. 3 provides an alternating pattern of electrical connections scheme in the vertical and horizontal directions of the array 300 that is similar to the scheme described in connection with FIG. 2A. The electrical pitch in the vertical dimension can be represented by the spacing between vertically aligned contacts, for example, the spacing between contact 308 and contact 314. The electrical pitch in the horizontal dimension is given by the spacing between horizontally aligned contacts, for example, the spacing between contact 316 and contact 320.

The optical pitch in the vertical dimension can be expressed as the distance between rows of lasers arrays, for example, the distance between the first row 306 and the second row 310. The optical pitch in the horizontal dimension can be expressed by the distance between columns of the laser arrays, for example, the distance between the first column 322 and the second column 324. Thus, for the configuration described in connection with FIG. 3, the array 300 has an optical pitch that is one half the electrical pitch in both the vertical and horizontal dimension.

In the configuration of FIG. 3, the die 302 has the same overall size as the die 104 described in connection with the known VCSEL array configuration shown in FIG. 1 and the same overall size of the die 202 of the VCSEL array configuration according to the present teaching shown in FIG. 2A. However, the VCSEL array described in connection with FIG. 3 has 64 individually addressable lasers 304, each with four apertures. In this particular configuration of electrodes, while maintaining the same electrical pitch in both the vertical and horizontal directions the array 300 shown in FIG. 3, the array 300 has four times as many individually addressable laser elements as the array 100 of FIG. 1.

This improvement in the state-of-the art is achieved by connecting both the rows (cathode connections) and the columns (anode connections) on only one side of a die, as opposed to both sides. Thus, in the example embodiment described in connection with FIG. 3, both an individually addressable row and an individually addressable column, which in this configuration each includes two emitter elements, has a pitch that is one half the pitch of the electrodes. In various embodiments of the present teaching, various combinations of the pitch of addressable rows and/or columns of laser arrays relative to the pitch of the electrodes associated with the addressable rows and/or columns of laser arrays can be obtained.

In one embodiment of the present teaching, different pitch ratios can be used along either or both of the vertical or horizontal direction to achieve desired independent control over portions of the entire laser array. For example, lower resolutions (larger groups of individually addressable emitters) can be used on the edges of the overall array and higher resolution (smaller groups of individually addressable emitters) can be used near the center of the overall array. An almost unlimited number of different patterns can be realized based on the size, position, and connection pattern of the electrodes in combination with the individual emitter size and position with respect to the electrodes to which they are connected.

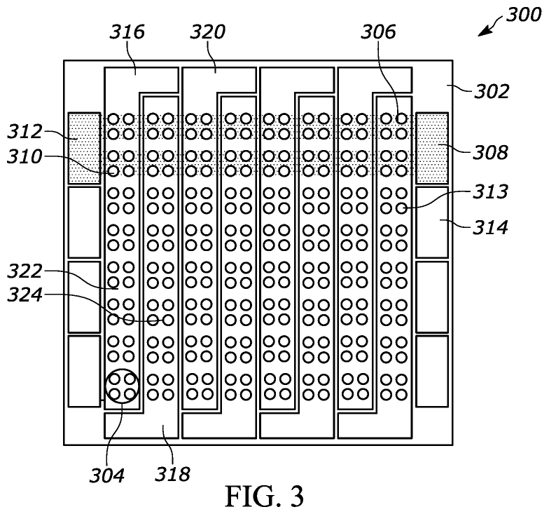

One feature of the present teaching is that the single ended contact configuration can be applied to both anode and cathode electrodes. FIG. 4 illustrates a top-view of a layout of a Vertical Cavity Surface Emitting Laser array for a LiDAR system with single-ended cathodes according to the present teaching. The array size is nominally 3.3 mm wide and 2.3 mm high. The electrical pitch in both the horizontal and vertical dimensions is 0.25. The optical pitch in the vertical dimension is half the electrical pitch. The optical pitch in the horizontal dimension is the same as the electrical pitch.

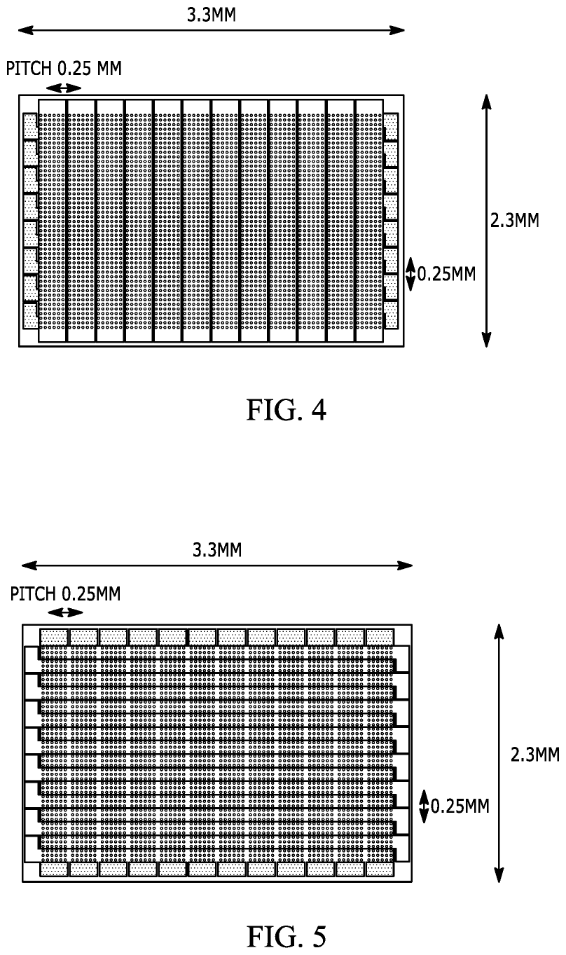

FIG. 5 illustrates a top-view of a layout of a Vertical Cavity Surface Emitting Laser array for a LiDAR system with single-ended anodes according to the present teaching. The array size is nominally 3.3 mm wide and 2.3 mm high. The electrical pitch in both the horizontal and vertical dimensions is 0.25. The optical pitch in the vertical dimension is half the electrical pitch. The optical pitch in the horizontal dimension is the same as the electrical pitch.

One skilled in the art will appreciate that there are numerous other VCSEL array configurations according to the present teaching where, for example, each row of emitters has a cathode contact on only one side of the die and that these configurations can be chosen to achieve various cost and/or performance objectives, such as achieving higher resolution and/or greater field-of-view at particular price points.

Also, it should be understood that the anode driver and the cathode driver design can impact the overall design of the laser array. The two types of drivers often have different costs to implement and these costs often drive the overall design. One feature of the present teaching is that the ability to provide a single-ended electrode for either the laser cathodes or the laser anodes allows the laser array optical and electrical pitch and the driver type to be optimized separately for various cost and/or performance metrics. As just one example, if a VCSEL array has a shape of N*M, where N is not equal to M, one skilled in the art will know how to select the lowest cost driver to drive the larger number of contacts.

### Equivalents

While the Applicant's teaching is described in conjunction with various embodiments, it is not intended that the Applicant's teaching be limited to such embodiments. On the contrary, the Applicant's teaching encompasses various alternatives, modifications, and equivalents, as will be appreciated by those of skill in the art, which may be made therein without departing from the spirit and scope of the teaching.

What is claimed is:

1. A matrix-addressable vertical cavity surface emitting laser array for light detection and ranging (LiDAR) systems, the laser array comprising a plurality of rows of vertical cavity surface emitting lasers formed on a die with one row of vertical cavity surface emitting lasers comprising a plurality of vertical cavity surface emitting lasers each configured with a common cathode electrical connection on one side of the die and another row of vertical cavity surface emitting lasers comprising a plurality of vertical cavity surface emitting lasers each configured with a common cathode electrical connection on the other side of the die, wherein each of the rows of vertical cavity surface emitting lasers is configured with anode connections that allow activating only a portion of the row at a particular time so that Class 1 eye safety can be maintained.

2. The matrix-addressable vertical cavity surface emitting laser array of claim 1 wherein the plurality of vertical cavity surface emitting lasers in at least some of the plurality of rows of vertical cavity surface emitting lasers are configured with a common anode electrical connection.

3. The matrix-addressable vertical cavity surface emitting laser array of claim 1 wherein at least one of the rows of vertical cavity surface emitting lasers is configured with anode connections that allow activating a portion of the vertical cavity surface emitting lasers in the at least one row of vertical cavity surface emitting lasers with a particular bias current so that Class 1 eye safety is maintained if vertical cavity surface emitting lasers in that portion of the row of vertical cavity surface emitting lasers are activated and Class 1 eye safety is exceeded of the entire at least one row of vertical cavity surface emitting lasers are activated.

4. The matrix-addressable vertical cavity surface emitting laser array of claim 1 wherein at least some of the plurality of rows of vertical cavity surface emitting lasers are arranged in a two-dimensional array.

5. The matrix-addressable vertical cavity surface emitting laser array of claim 1 wherein a spacing between electrical contacts connecting the common cathode electrical connection on one side of the die is greater than a spacing between rows of vertical cavity surface lasers.

6. The matrix-addressable vertical cavity surface emitting laser array of claim 1 wherein a spacing between electrical contacts connecting the common cathode electrical connection on one side of the die is twice a spacing between rows of vertical cavity surface lasers.

7. The matrix-addressable vertical cavity surface emitting laser array of claim 1 wherein a pitch of rows of vertical cavity surface emitting lasers is different from a pitch of electrical cathode connections.

8. The matrix-addressable vertical cavity surface emitting laser array of claim 1 wherein the plurality of rows of vertical cavity surface emitting lasers are arranged in columns where vertical cavity surface emitting lasers in each column has a common anode connection.

9. The matrix-addressable vertical cavity surface emitting laser array of claim 8 wherein alternating columns of vertical cavity surface emitting lasers have anode connections to the die on alternating sides of the die.

10. The matrix-addressable vertical cavity surface emitting laser array of claim 1 wherein each of the plurality of rows of vertical cavity surface emitting lasers has the same number of vertical cavity surface emitting lasers.

11. The matrix-addressable vertical cavity surface emitting laser array of claim 1 wherein at least one of the plurality of rows of vertical cavity surface emitting lasers has a different number of vertical cavity surface emitting lasers than another one of the plurality of rows of vertical cavity surface emitting lasers.

12. The matrix-addressable vertical cavity surface emitting laser array of claim 1 wherein at least some of the vertical cavity surface emitting lasers in the plurality of rows of surface emitting lasers comprise top emitting lasers.

13. The matrix-addressable vertical cavity surface emitting laser array of claim 1 wherein at least some of the vertical cavity surface emitting lasers in the plurality of rows of surface emitting lasers comprise bottom emitting lasers.

14. The matrix-addressable vertical cavity surface emitting laser array of claim 1 wherein at least some of the vertical cavity surface emitting lasers in the plurality of rows of surface emitting lasers comprise vertical external-cavity surface emitting lasers.

15. A matrix-addressable vertical cavity surface emitting laser array for light detection and ranging (LiDAR) systems, the laser array comprising a plurality of rows and a plurality of columns of vertical cavity surface emitting lasers formed on a die, a first row of vertical cavity surface emitting lasers comprising a plurality of vertical cavity surface emitting lasers each configured with a common cathode electrical connection on one side of the die, the laser array being arranged so that each of the plurality of columns of vertical cavity surface emitting lasers comprises a plurality of vertical cavity surface emitting lasers configured with a common anode electrical connection that allows activating only a portion of a row at a particular time so that Class 1 eye safety can be maintained, wherein alternating columns of vertical cavity surface emitting lasers have anode connections on alternating sides of the die.

16. The matrix-addressable vertical cavity surface emitting laser array of claim 15 wherein the first row of vertical cavity surface emitting lasers comprising the plurality of vertical cavity surface emitting lasers each configured with the common cathode electrical connection on one side of the die is configured with anode connections that allow activating a portion of the vertical cavity surface emitting lasers in the first row of vertical cavity surface emitting lasers with a particular bias current so that Class 1 eye safety is maintained if vertical cavity surface emitting lasers in that portion of the first row of vertical cavity surface emitting lasers are activated and Class 1 eye safety is exceeded if the entire first row of vertical cavity surface emitting lasers are activated.

17. The matrix-addressable vertical cavity surface emitting laser array of claim 15 wherein a second row of the plurality of row of vertical cavity surface emitting lasers comprising a plurality of vertical cavity surface emitting lasers each configured with a common cathode electrical connection on another side of the die.

18. The matrix-addressable vertical cavity surface emitting laser array of claim 15 wherein at least some of the plurality of rows of vertical cavity surface emitting lasers are arranged in a two-dimensional array.

19. The matrix-addressable vertical cavity surface emitting laser array of claim 15 wherein a spacing between electrical contacts connecting the common cathode electrical connection on one side of the die is greater than a spacing between rows of vertical cavity surface lasers.

20. The matrix-addressable vertical cavity surface emitting laser array of claim 15 wherein a spacing between electrical contacts connecting the common cathode electrical connection on one side of the die is twice a spacing between rows of vertical cavity surface lasers.

21. The matrix-addressable vertical cavity surface emitting laser array of claim 15 wherein a pitch of rows of vertical cavity surface emitting lasers is different from a pitch of electrical cathode connections.

22. The matrix-addressable vertical cavity surface emitting laser array of claim 15 wherein each of the plurality of rows of vertical cavity surface emitting lasers has the same number of vertical cavity surface emitting lasers.

23. The matrix-addressable vertical cavity surface emitting laser array of claim 15 wherein at least one of the plurality of rows of vertical cavity surface emitting lasers has a different number of vertical cavity surface emitting lasers than another one of the plurality of rows of vertical cavity surface emitting lasers.

24. The matrix-addressable vertical cavity surface emitting laser array of claim 15 wherein at least some of the vertical cavity surface emitting lasers in the plurality of rows of surface emitting lasers comprise top emitting lasers.

25. The matrix-addressable vertical cavity surface emitting laser array of claim 15 wherein at least some of the vertical cavity surface emitting lasers in the plurality of rows of surface emitting lasers comprise bottom emitting lasers.

26. The matrix-addressable vertical cavity surface emitting laser array of claim 15 wherein at least some of the vertical cavity surface emitting lasers in the plurality of rows of surface emitting lasers comprise vertical external-cavity surface emitting lasers.
